(19) United States
(12) Patent Application Publication
(10) Pub. No.: US 2006/0145233 A1
(43) Pub. Date: Jul. 6, 2006

(54) Method of fabricating a semiconductor device capacitor having a dielectric barrier layer and a semiconductor device capacitor having the same

(75) Inventors: Kyong-Min Kim, Ansan-si (KR); Dong-Jun Kim, Cheonan-si (KR); Kwang-Woon Lee, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/320,385

(22) Filed: Dec. 28, 2005

(30) Foreign Application Priority Data
Dec. 31, 2004 (KR) 2004-118002

(51) Int. Cl. H01L 29/00; H01L 21/36

(52) U.S. Cl. 257/306; 438/396; 438/240; 257/310; 257/532

(57) ABSTRACT

A method of forming a capacitor of a semiconductor device is provided. In the method, a capacitor lower electrode is deposited on a semiconductor substrate and then a dielectric layer is deposited on the lower electrode. A dielectric barrier layer is deposited on an upper part of the dielectric layer. The dielectric barrier layer comprises a material for preventing degradation of a leakage current characteristic of the dielectric layer. The method further comprises depositing a capacitor upper electrode on an upper part of the dielectric barrier layer.

This application claims priority from Korean Patent Application No. 10-2004-0118002 filed on Dec. 31, 2004 in the Korean Intellectual Property Office, the disclosure of which is incorporated herein by reference in its entirety.

### BACKGROUND OF THE INVENTION

1. Field of the Invention

The present invention relates to a method of fabricating a capacitor of a semiconductor device and to a capacitor of the semiconductor device, and more particularly, to a method of forming a capacitor of a semiconductor device having a dielectric barrier layer and to a capacitor of a semiconductor device having the same.

2. Description of the Related Art

As the integration density of memory devices and/or merged dynamic random access(DRAM) with logic(MDL) semiconductor devices increases, data stored in the capacitors of these devices is frequently damaged due to external charges. To prevent damage to the data in the above-mentioned devices, sufficient memory cell capacitance is required. Accordingly, various methods for providing sufficient cell capacitance have been utilized. One such method is to manufacture the capacitor of these memory cells using a material having a high dielectric constant as a dielectric layer interposed between a lower electrode and an upper electrode.

For example, conventional capacitors of semiconductor memory devices include a lower electrode and an upper electrode that are formed of metal or silicon, and a dielectric layer which is interposed between them. The dielectric layer is formed of a material having a high dielectric constant. A metal oxide layer is generally used as the material having the high dielectric constant. Typically, the metal oxide layer is formed of a single layer of aluminum oxide (Al₂O₃ ), or hafnium oxide (HfO₂ ) or a stacked layer thereof. However, one of the difficulties with conventional methods for fabricating capacitors is that during a deposition process the dielectric layer is etched due to a chloride (Cl) group generated from a titanium tetrachloride (TiCl₄) gas used to form a titanium nitride (TiN) upper electrode layer. The above-mentioned etching of the dielectric layer results in the degradation of the leakage current characteristic of the dielectric layer. Thus, there is a need for a capacitor for a semiconductor device which not only has a dielectric layer comprised of a material having a sufficiently high dielectric constant but which also comprises a dielectric barrier layer for preventing degradation of the dielectric layer, thereby also providing an improved leakage current characteristic over conventional capacitors.

### SUMMARY OF THE INVENTION

According to an exemplary embodiment of the present invention, a method of forming a capacitor for a semiconductor device is provided. The method comprises forming a capacitor lower electrode on a semiconductor substrate, forming a dielectric layer on the lower electrode, forming a dielectric barrier layer on an upper part of the dielectric layer. The dielectric barrier layer comprises a material for preventing degradation of a leakage current characteristic of the dielectric layer. The method further comprises forming a capacitor upper electrode on an upper part of the dielectric barrier layer.

According to another exemplary embodiment of the present invention, a capacitor for a semiconductor device is provided. The capacitor comprises a capacitor lower electrode formed on an upper part of a semiconductor substrate, a dielectric layer formed on an upper part of the lower electrode, a dielectric barrier layer formed on an upper part of the dielectric layer. The dielectric barrier layer comprises a material for preventing degradation of a leakage current characteristic of the dielectric layer. The capacitor further comprises a capacitor upper electrode formed on an upper part of the dielectric barrier layer.

### BRIEF DESCRIPTION OF THE DRAWINGS

FIGS. 1 through 6 are cross-sectional views for illustrating a method of forming a capacitor having a dielectric barrier layer according to an exemplary embodiment of the present invention.

### DETAILED DESCRIPTION OF EXEMPLARY EMBODIMENTS OF THE INVENTION

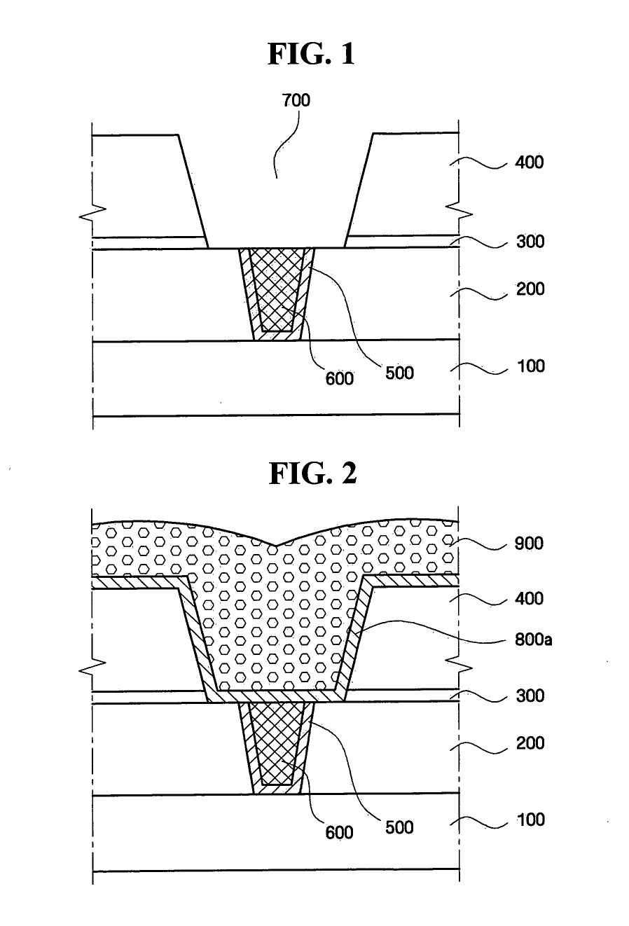

A method of forming a capacitor for a semiconductor device having a dielectric barrier layer according to an exemplary embodiment of the present invention will be described more fully with reference to FIGS. 1 through 6. Although a method of forming a cell capacitor of a dynamic random access memory (DRAM) is shown in FIGS. 1 through 6, it is noted that this method can be applied to capacitors of other devices including but not limited to next generation memory devices or the like.

FIG. 1 illustrates the steps of forming a region 700 where a capacitor is to be formed in accordance with the present exemplary embodiment.

Referring to FIG. 1, a lower insulating layer 200 is formed on a semiconductor substrate 100. A contact region is then formed using a photolithographic process and an etching process. A contact barrier layer 500 and a plug layer 600 are formed inside the contact region. The contact barrier layer 500 can be formed of any one of the following materials, including but not limited to a transition metal, a transition metal alloy and a transition metal compound, or a combination thereof. For example, a single layer of tantalum (Ta), tantalum nitride (TaN), tantalum silicon nitride (TaSiN), titanium nitride (TiN), titanium silicon nitride (TiSiN), tungsten nitride (WN), or tungsten silicon nitride (WSiN) or a composite layer such as a titanium (Ti)/titanium nitride (TiN) layer can be used. The plug layer 600 is completed by an etchback process or a chemical mechanical polishing(CMP) process using tungsten or the like. Subsequently, an etch stop layer 300 and an upper insulating layer 400 are formed and the region 700 where the capacitor is to be formed is etched. The etch stop layer 300 is formed between the lower insulating layer 200 and the upper insulating layer 400 so as to prevent the lower insulating layer 200 from being etched during etching of the upper insulating layer 400. Moreover, the etch stop layer 300 is etched subsequent to etching the upper insulating layer 400.

FIG. 2 illustrates the steps of forming a lower electrode conductive layer 800a in accordance with the present exemplary embodiment.

Referring to FIG. 2, the lower electrode conductive layer 800a of the capacitor is deposited on the resultant structure depicted in FIG. 1. The lower electrode conductive layer 800a can be formed of any of the following materials including but not limited to a metal layer, a metal alloy layer, a metal compound layer, a polysilicon layer or stack layer thereof. For example, Al, Ta, TaN, TaSiN, TiN, TiSiN, WN, or WSiN layer or a stack layer thereof can be used. Further, a double or a triple layer comprising a combination of the above-described layer and a copper (Cu) or a Cu-alloy layer can be used. For example, a double layer comprising a Ta layer and a Cu layer, or a double layer comprising a TaN layer and a Cu layer can be used. Alternatively, a triple layer comprising a Ta layer, a TaN layer, and a Cu layer, or a triple layer comprising a TiN layer, a AlCu layer and a TiN layer can be used. Subsequently, a coating process is used to form a photoresist layer 900 for filling the inside of the region 700 where the capacitor is to be formed.

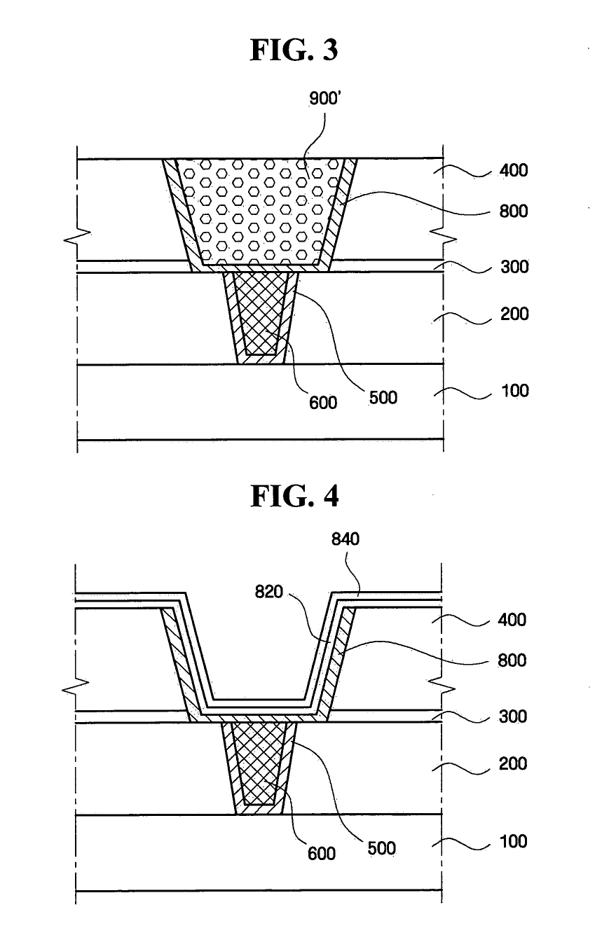

FIG. 3 illustrates the steps of completing a lower electrode 800 in accordance with the present exemplary embodiment.

Referring to FIG. 3, the coated photoresist layer 900 is etched back using an etchback process to become filled photoresist 900′ which remains only on the inside of the region 700 where the capacitor is to be formed. At the same time, a part of the lower electrode conductive layer 800a exposed by the etching of the above photoresist is etched using the same process described above, such that the lower electrode 800 remains within the region 700 where the capacitor is to be formed.

FIG. 4 illustrates the steps of forming a dielectric layer in accordance with the present exemplary embodiment.

Referring to FIG. 4, the filled photoresist 900′ is first removed using a photoresist strip process and then the dielectric layer is formed. The dielectric layer can be comprised of for example, a single layer comprised of Al₂O₃, HfO₂ or a stack layer thereof, or the like. While the Al₂O₃ layer has an excellent leakage current characteristic, the dielectric constant of the Al₂O₃ layer is about 8-10. On the other hand, while the HfO₂ layer has a very high dielectric constant of about 20, the HfO₂ layer itself is not able to ensure an appropriate leakage current characteristic. However, a sufficient dielectric constant and an improved leakage current characteristic is provided, for example, by forming a stack layer comprising an Al₂O₃ layer 820 and an HfO₂ layer 840, as shown in FIG. 4.

First, the Al₂O₃ layer 820 is deposited to a thickness of about 10-30 angstroms (Å) by an atomic layer deposition(ALD) process using trimethylaluminum(TMA) at a temperature of about 300-500° C. Al₂O₃ layer 820 is deposited by repeating a cycle comprising a TMA source supply, a purge gas such as N₂ gas, an O₃ gas as a reactive gas, a supply and purge gas such as N₂ gas.

Next, the HfO₂ layer 840 is deposited to a thickness of about 30-60 Å by the ALD process using tetraethylaminehafnium(TEMAH) at a temperature of about 250-350° C. Similar to Al₂O₃ deposition process, O₃ gas can be used as a reactive gas.

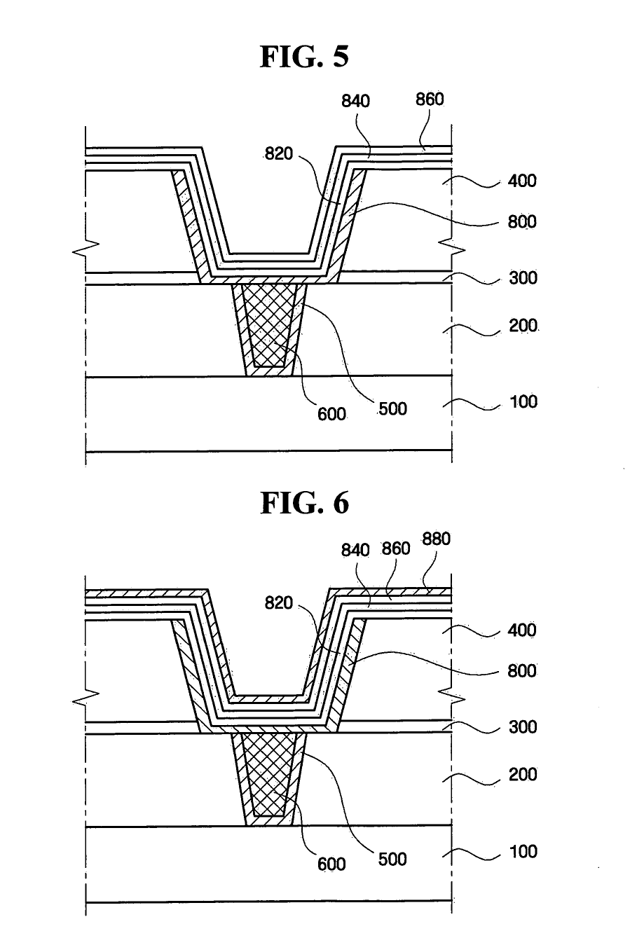

FIG. 5 illustrates the steps of forming a dielectric barrier layer 860 in accordance with the present exemplary embodiment.

The dielectric barrier layer 860 can be comprised of tantalum oxide (Ta₂O₅) using the ALD process. In this process, tantalum ethoxide (Ta(OC₂H₅)) is used as a source gas and O₃ gas is injected as a reactive gas. Further, the dielectric barrier layer 860 is deposited to a thickness of about 5-10 Å at a deposition temperature of about 300-400° C. The dielectric barrier layer 860 is deposited on the HfO₂ layer 840, thereby functioning as a protective layer for the HfO₂ layer 840, or dielectric layer.

TiCl₄ is used in a subsequent deposition process to form an upper electrode of the capacitor. It is also noted that if a dielectric barrier layer 860 such as the one described above were not present in the formation of the capacitor then during the above subsequent deposition process to form the upper electrode, a Cl group of TiCl₄ would react with the HfO₂ layer 840 to produce a by product of gaseous hafnium chloride (HfCl₄) and solid titanium dioxide (TiO₂). Consequently, the by-product of gaseous HfCl₄ and solid TiO₂ would be separated from the HfO₂ layer 840, thereby resulting in the etching of the HfO₂ layer 840. The above-described etching of the HfO₂ layer 840 results in degradation of the leakage current characteristic of the HfO₂ layer 840.

FIG. 6 illustrates the steps of forming an upper electrode of the capacitor in accordance with the present exemplary embodiment.

An upper electrode 880 can be formed for example of a TiN layer. In the present exemplary embodiment, TiCl₄ and NH₃ gases are used to form the TiN layer. In addition, the upper electrode 880 is formed to a thickness of about 200-400 Å at a temperature of about 500-700° C.

As described above, a capacitor having a dielectric barrier layer according to exemplary embodiments of the present invention, is a capacitor wherein the degradation of a leakage current characteristic of a dielectric layer caused by the etching of a surface of the dielectric layer formed on a lower part of an upper electrode is prevented.

Having described the exemplary embodiments of the present invention, it is further noted that various modifications can be made herein without departing from the spirit and scope of the invention as defined by the metes and bounds of the appended claims.

What is claimed is:

1. A method of forming a capacitor for a semiconductor device comprising:
forming a capacitor lower electrode on a semiconductor substrate;
forming a dielectric layer on the lower electrode;
forming a dielectric barrier layer on an upper part of the dielectric layer, said dielectric barrier layer comprises a material for preventing degradation of a leakage current characteristic of the dielectric layer; and
forming a capacitor upper electrode on an upper part of the dielectric barrier layer.

2. The method of claim 1, wherein the dielectric layer is a composite layer.

3. The method of claim 2, wherein at least one layer of the composite layer is an aluminum oxide (Al₂O₃) layer.

4. The method of claim 2, wherein the aluminum oxide (Al₂O₃) layer is formed to a thickness of about 10-30 Å.

5. The method of claim 3, wherein the composite layer comprises the Al₂O₃ layer and a hafnium oxide (HfO₂) layer.

6. The method of claim 5, wherein the dielectric barrier layer comprises tantalum oxide (Ta₂O₅ ).

7. The method of claim 2, wherein at least one layer of the composite layer is a hafnium oxide (HfO₂) layer.

8. The method of claim 7, wherein the HfO₂ layer is formed to a thickness of about 30-60 Å.

9. The method of claim 1, wherein the dielectric barrier layer comprises a Ta₂O₅ layer.

10. The method of claim 9, wherein the dielectric barrier layer is formed to a thickness of about 5-10 Å.

11. The method of claim 1, wherein the dielectric barrier layer is deposited to a thickness of about 5-10 Å.

12. The method of claim 1, wherein the upper electrode comprises a titanium nitride (TiN) layer.

13. The method of claim 12, wherein the TiN layer is formed to a thickness of about 500-700 Å.

14. A capacitor for a semiconductor device comprising:
a capacitor lower electrode formed on an upper part of a semiconductor substrate;
a dielectric layer formed on an upper part of the lower electrode;
a dielectric barrier layer formed on an upper part of the dielectric layer, said dielectric barrier layer comprises a material for preventing degradation of a leakage current characteristic of the dielectric layer; and
a capacitor upper electrode formed on an upper part of the dielectric barrier layer.

15. The capacitor of claim 14, wherein the dielectric layer is a composite layer.

16. The capacitor of claim 15, wherein at least one layer of the composite layer is an aluminum oxide (Al₂O₃) layer.

17. The capacitor of claim 16, wherein the Al₂O₃ layer is formed to a thickness of about 10-30 Å.

18. The capacitor of claim 15, wherein the composite layer comprisesan aluminum oxide (Al₂O₃) layer and a hafnium oxide (HfO₂) layer.

19. The capacitor of claim 18, wherein the dielectric barrier layer comprises tantalum oxide (Ta₂O₅).

20. The capacitor of claim 15, wherein at least one layer of the composite layer is a hafnium oxide (HfO₂) layer.

21. The capacitor of claim 20, wherein the HfO₂ layer is formed to a thickness of about 30-60 Å.

22. The capacitor of claim 14, wherein the dielectric barrier layer comprises a tantalum oxide (Ta₂O₅) layer.

23. The capacitor of claim 19, wherein the dielectric barrier layer is formed to a thickness of about 5-10 Å.

24. The capacitor of claim 14, wherein the dielectric barrier layer is formed to a thickness of about 5-10 Å.

25. The capacitor of claim 14, wherein the upper electrode comprises a titanium nitride (TiN) layer.

26. The capacitor of claim 25, wherein the TiN layer is formed to a thickness of about 500-700 Å.
